(19) United States
(12) Patent Application Publication
(10) Pub. No.: US 2008/0121977 A1
(43) Pub. Date: May 29, 2008

(54) Semiconductor device and method of manufacturing having the same

(76) Inventors: Yong-Soon Choi, Seoul (KR); Hong-Gun Kim, Suwon-si (KR); Jong-Wan Choi, Suwon-si (KR); Eun-Kyung Baek, Suwon-si (KR); Ju-Seon Goo, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/699,419

(22) Filed: Jan. 30, 2007

(30) Foreign Application Priority Data
Nov. 3, 2006 (KR) 2006-108098

(51) Int. Cl. H01L 29/788; H01L 21/04

(52) U.S. Cl. 257/321; 257/632; 438/425; 438/591; 257/E29.3; 257/E21.04

(57) ABSTRACT

A semiconductor device includes a substrate having a trench, a liner layer pattern on sidewalls and a bottom surface of the trench, the liner layer pattern including a first oxide layer pattern and a second oxide layer pattern, a diffusion blocking layer pattern on the liner layer pattern, and an isolation layer pattern in the trench on the diffusion blocking layer pattern.

### BACKGROUND OF THE INVENTION

1. Field of the Invention

Embodiments of the present invention relate to a semiconductor device and a method of manufacturing the semiconductor device. More particularly, embodiments of the present invention relate to a semiconductor device that may be applied to a semiconductor memory device such as a non-volatile memory and a method of manufacturing the semiconductor device.

2. Description of the Related Art

A semiconductor device may include an isolation layer, e.g., to define an active region. The isolation layer may be an oxide that is formed in a trench, e.g., by a chemical vapor deposition (CVD) process, in order to electrically isolate elements formed on a substrate. It may be desirable to form the isolation layer without producing a void or a seam in the trench: The trench may be relatively narrow and may be filled with the isolation layer.

Another approach to forming an isolation layer may employ a spin-on-glass (SOG) material such as polysilazane, which may be deposited so as to fill the trench. The SOG material may then be changed into an oxide by, e.g., a thermal treatment process. For example, after the trench is filled with polysilazane, the oxide isolation layer may be formed by thermally treating the polysilazane-filled trench under a predetermined atmosphere, e.g., a water (H₂O)/oxygen (O₂) atmosphere. However, when such an isolation layer forms part of a non-volatile memory device such as a flash memory device, during the above-mentioned thermal treatment process, H₂O ingredients and/or O₂ ingredients may diffuse into a tunnel oxide layer of the non-volatile memory device. This may deteriorate properties of the tunnel oxide layer and oxidize a floating gate on the tunnel oxide layer, thereby decreasing electric properties and a reliability of the non-volatile memory device.

In an effort to avoid such problems, after a trench is formed on a semiconductor substrate and an inner oxide layer is formed on a sidewall of the trench, a plasma nitride layer may be formed on the inner oxide layer. However, even in the case of the semiconductor device including the plasma nitride layer, it remains difficult to prevent the diffusion of oxygen from the thermal treatment used to form the isolation layer.

### SUMMARY OF THE INVENTION

The present invention is therefore directed to an isolation structure, a method of forming the isolation structure, a semiconductor device having the isolation structure, and a method of manufacturing the semiconductor device, which substantially overcome one or more of the problems due to the limitations and disadvantages of the related art.

It is therefore a feature of an embodiment of the present invention to provide an isolation structure having an excellent gap-filling characteristic and capable of preventing a deterioration of a tunnel oxide layer.

It is therefore a feature of an embodiment of the present invention to provide an isolation structure having a diffusion barrier layer and a liner layer in a trench.

It is therefore a further feature of an embodiment of the present invention to provide a semiconductor device having improved electrical properties structure and reliability with the isolation layer.

At least one of the above and other features and advantages of the present invention may be realized by providing a semiconductor device, including a substrate having a trench, a liner layer pattern on sidewalls and a bottom surface of the trench, the liner layer pattern including a first oxide layer pattern and a second oxide layer pattern, a diffusion blocking layer pattern on the liner layer pattern, and an isolation layer pattern in the trench on the diffusion blocking layer pattern.

The semiconductor device may further include an inner oxide layer between the liner layer pattern and the trench. The diffusion blocking layer pattern may include oxynitride. The semiconductor device may further include a compensation layer in the trench on the isolation layer pattern. The compensation layer may include high density plasma oxide. A thickness of the liner layer pattern may be greater than or equal to about 100 Å.

The semiconductor device may further include a tunnel oxide layer pattern on the substrate adjacent to the trench, wherein the tunnel oxide layer pattern may have a floating gate thereon, and a dielectric layer on the isolation layer pattern, the diffusion blocking layer pattern, the liner layer patter and the floating gate, wherein a control gate may be on the dielectric layer. The dielectric layer may be on a compensation layer, the compensation layer separating the dielectric layer from the isolation layer pattern, the diffusion blocking layer pattern and the liner layer pattern.

At least one of the above and other features and advantages of the present invention may also be realized by providing a method of manufacturing a semiconductor device, including forming a trench on a surface of a substrate, forming a liner layer pattern on sidewalls and a bottom surface of the trench, the liner layer pattern including a first oxide layer pattern and a second oxide layer pattern, forming a diffusion blocking layer pattern on the liner layer pattern, and forming an isolation layer pattern in the trench on the diffusion blocking layer pattern.

The method may further include forming an inner oxide layer on the sidewalls and the bottom surface of the trench before forming the liner layer pattern. Forming the liner layer pattern may include forming a first oxide layer on the sidewalls and the bottom surface of the trench, and forming a second oxide layer on the first oxide layer. Forming the diffusion blocking layer pattern and the isolation layer pattern may include forming a preliminary diffusion blocking layer on the second oxide layer, forming a preliminary isolation layer on the preliminary diffusion blocking layer to fill up the trench, and thermally treating the preliminary isolation layer and the preliminary diffusion blocking layer to convert the preliminary isolation layer and the preliminary diffusion blocking layer into an isolation layer and a diffusion blocking layer, respectively.

The preliminary diffusion blocking layer may be formed using a nitride and the preliminary isolation layer may be formed using a polysilazane. Thermally treating the preliminary isolation layer and the preliminary diffusion blocking layer may include a first thermal treatment at a temperature of about 200° C. to about 400° C., and a second thermal treatment at a temperature of about 400° C. to about 1,000° C. The second thermal treatment may be performed in an atmosphere that includes one of a mixture of water vapor and an oxygen gas, and a mixture of water vapor and a nitrogen gas.

The preliminary isolation layer and the preliminary diffusion blocking layer may be converted into the isolation layer and the diffusion blocking layer simultaneously.

The method may further include forming the isolation layer pattern, the liner layer pattern, and the diffusion blocking layer pattern by partially removing respective portions of the isolation layer, a liner layer, and the diffusion blocking layer, such that an uppermost extent of the isolation layer pattern, an uppermost extent of the liner layer pattern, and an uppermost extent of the diffusion blocking layer pattern may be below an upper surface of the substrate. The method may further include forming a tunnel oxide layer pattern and a floating gate on the substrate, the tunnel oxide layer pattern and the floating gate being adjacent to the trench, forming a dielectric layer on the isolation layer pattern, the diffusion blocking layer pattern, the liner layer pattern, and the floating gate, and forming a control gate on the dielectric layer.

Forming the tunnel oxide layer pattern and the floating gate may include forming a tunnel oxide layer and a floating gate layer on the substrate before forming the trench. A thickness of the liner layer pattern may be greater than or equal to about 100 Å.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 to 9 illustrate cross-sectional views of stages in a method of fabricating a semiconductor memory device including an isolation structure in accordance with an embodiment of the present invention; and

FIG. 10 illustrates a graph of breakdown voltage measurements of an isolation structure formed in accordance with an embodiment of the present invention and a comparative structure.

### DETAILED DESCRIPTION OF THE INVENTION

Korean Patent Application No. 2006-108098, filed on Nov. 3, 2006, in the Korean Intellectual Property Office, and entitled: “Isolation Structure, Method of Forming the Isolation Structure, Semiconductor Device Having the Isolation Structure and Method of Manufacturing the Semiconductor Device Having the Isolation Structure,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as being limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will be understood that when an element or layer is referred to as being “on,” “connected to,” or “coupled to” another element or layer, it can be directly on, connected or coupled to the other element or layer, or intervening elements or layers may be present. In contrast, when an element is referred to as being “directly on,” “directly connected to,” or “directly coupled to” another element or layer, there are no intervening elements or layers present. Like reference numerals refer to like elements throughout.

As used herein, the term “and/or” includes any and all combinations of one or more of the associated listed items. It will be understood that, although the terms “first,” “second,” “third,” etc., may be used herein to describe various elements, components, regions, layers and/or sections, these elements, components, regions, layers and/or sections should not be limited by these terms. These terms are only used to distinguish one element, component, region, layer and/or section from another element, component, region, layer and/or section. Thus, a first element, component, region, layer and/or section discussed below could be termed a second element, component, region, layer and/or section without departing from the teachings of the present invention.

Spatially relative terms, such as “beneath,” “below,” “lower,” “above,” “upper,” etc., may be used herein for ease of description to describe one element or feature's relationship to another element(s) or feature(s) illustrated in the figures. It will be understood, however, that the spatially relative terms are intended to encompass different orientations of the device in use or operation, in addition to the orientation depicted in the figures. Thus, the device may be otherwise oriented (rotated 90 degrees or at other orientations) and the spatially relative descriptors used herein interpreted accordingly.

The terminology used herein is for the purpose of describing particular embodiments only, and is not intended to be limiting of the present invention. As used herein, the singular forms “a,” “an” and “the” are intended to include the plural forms as well, unless the context clearly indicates otherwise. It will be further understood that the terms “comprises” and/or “comprising” specify the presence of stated features, integers, steps, operations, elements, and/or components, but do not preclude the presence or addition of one or more other features, integers, steps, operations, elements, and/or components, and/or groups thereof.

Embodiments of the present invention are described herein with reference to illustrations that are schematics of idealized embodiments and intermediate structures. As such, variations from the shapes of the illustrations, as a result, for example, of manufacturing techniques and/or tolerances, are to be expected. Thus, embodiments of the present invention should not be construed as being limited to the particular shapes of regions illustrated herein, but are to include deviations in shapes that result, for example, from manufacturing. For example, an implanted region that is illustrated as a rectangle may have rounded or curved features and/or a gradient of implant concentration at its edges, rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms, including technical and scientific terms, used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIGS. 1 to 9 illustrate cross-sectional views of stages in a method of fabricating a semiconductor memory device including an isolation structure in accordance with an embodiment of the present invention. Although a non-volatile memory device such as a flash memory device may be described in connection with FIGS. 1 to 9, those skilled in the art will readily appreciate that other applications are similarly encompassed, e.g., other semiconductor devices, volatile memories such as dynamic random access memory (DRAM) and static random access memory (SRAM), etc.

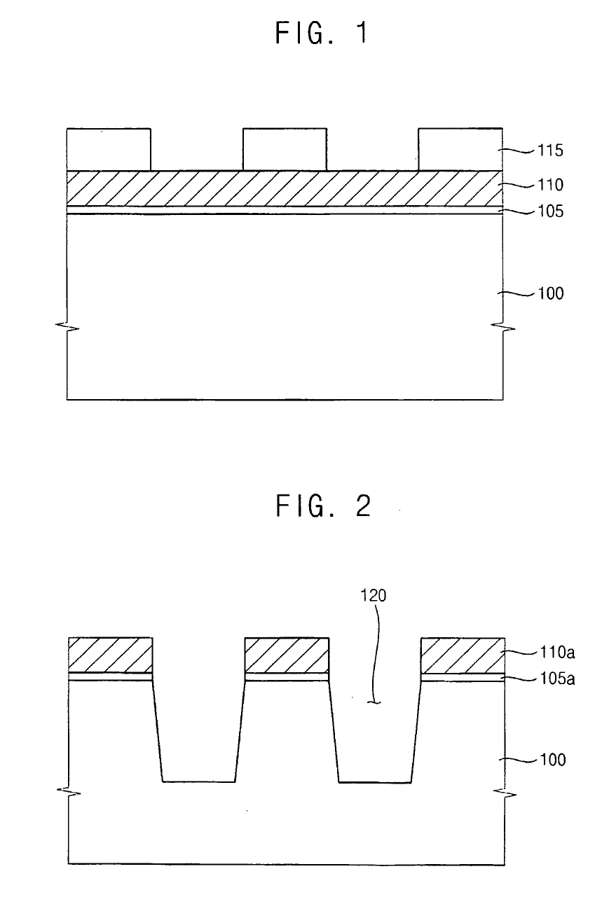

Referring to FIG. 1, a tunnel oxide layer 105 and a first conductive layer 110, which may be used to form a floating gate 110a (see FIG. 2), may be successively formed on a substrate 100.

The substrate 100 may include a semiconductor substrate such as a silicon wafer, a silicon-on-insulator (SOI) substrate, a metal oxide single crystalline substrate, etc. In an embodiment of the present invention, the tunnel oxide layer 105 may include, e.g., silicon oxide. The tunnel oxide layer 105 may be formed by, e.g., a thermal oxidation process, a CVD process, etc. The first conductive layer 110 may include, e.g., polysilicon doped with impurities. The first conductive layer 110 may be formed by, e.g., a CVD process, a low pressure chemical vapor deposition (LPCVD) process, a plasma-enhanced chemical vapor deposition (PECVD) process, etc.

A mask 115 for forming a trench 120 (see FIG. 2) may be formed on the first conductive layer 110. The mask 115 may be formed using a material having an etching selectivity with respect to the first conductive layer 110, the tunnel oxide layer 105 and the substrate 100. For example, the mask 115 may include nitride such as silicon nitride, oxynitride such as silicon oxynitride, etc. In an implementation (not shown), the mask 115 may be formed by forming a mask layer on the first conductive layer 110, after which the mask layer may be patterned by an etching process to form the mask 115 on the first conductive layer 110.

Referring to FIG. 2, the first conductive layer 110, the tunnel oxide layer 105 and the substrate 100 may be etched to form the trench 120 in a surface of the substrate 100, and to form a tunnel oxide layer pattern 105a and a floating gate 110a on the substrate 100.

The trench 120 may be formed to have a predetermined depth, as determined from an upper surface of the substrate 100. Further, the trench 120 may have sidewalls having a predetermined angle of inclination with respect to a direction normal to the upper surface of the substrate 100. The trench 120 may be formed by, e.g., an anisotropic etching process. After the trench 120 is formed, the mask 115 may be removed.

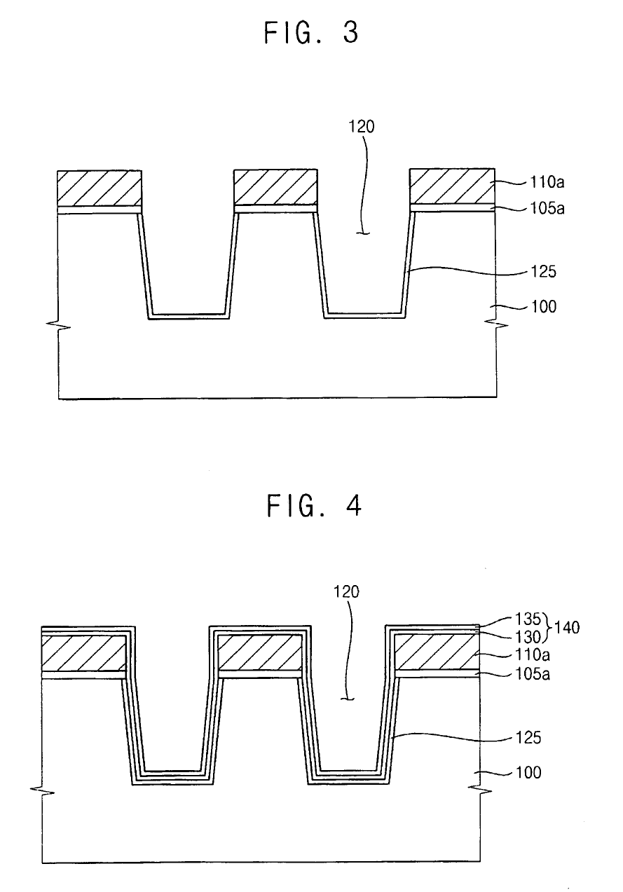

Referring to FIG. 3, an inner oxide layer 125 may be formed on inner surfaces of the trench, i.e., on the sidewalls and a bottom surface of the trench 120. Forming the inner oxide layer 125 may help repair damage to the substrate 100 that occurs during the etching process used to form the trench 120. In an implementation, the inner oxide layer 125 may be formed by a thermal oxidation process, whereby a portion of the substrate that defines the sidewalls and the bottom surface of the trench 120 may be partially thermally oxidized to form the inner oxide layer 125 on the sidewalls and the bottom surface of the trench 120.

Referring to FIG. 4, a liner layer 140 may be formed on the sidewalls of the trench 120, on the bottom surface of the trench 120 and on the floating gate 110a. In particular, the liner layer 140 may entirely cover the inner oxide layer 125. The liner layer 140 may be formed on the inner oxide layer 125, on the sidewalls of the tunnel oxide layer pattern 105a that are exposed in the trench 120, and on sidewalls and an upper surface of the floating gate 110a. Thus, the liner layer 140 may be formed to continuously cover the substrate 100 from the bottom surface of the trench 120 to the upper surface of the floating gate 110a. The liner layer 140 may include middle temperature oxide (MTO), HDP oxide, flowable oxide (FOX), etc., which may be used alone or in combination.

The liner layer 140 may include a first oxide layer 130 and a second oxide layer 135, which may be successively stacked on the exposed surfaces of the trench 120, the polysilicon pattern 110a, and the tunnel oxide layer pattern 105a. In an implementation, the first oxide layer 130 may include MTO and the second oxide layer 130 may include HDP oxide. The first oxide layer 130 and the second oxide layer 135 may be formed by, e.g., a CVD process, an LPCVD process, a PECVD process, a high density plasma chemical vapor deposition (HDPCVD) process, etc. The liner layer 140 may be a conformal layer that has a substantially uniform thickness.

In an implementation, the liner layer 140 may have a thickness of about 100 Å or more. The liner layer 140 may reduce or eliminate the diffusion of oxygen into the tunnel oxide layer pattern 105a and the substrate 100 adjacent to the tunnel oxide layer pattern 105a during a subsequent process of forming an isolation layer 160, which is described below in connection with FIG. 6.

The liner layer 140 may have a predetermined thickness relative to the width and/or depth of the trench 120. In an implementation, the liner layer 140 may have a thickness of less than or equal to about 30% of the width of the trench 120. The width of the trench 120 may be determined at the upper surface of the substrate 100. In an implementation, the liner layer 140 may have a thickness that is less than or equal to about 20% of the depth of the trench 120.

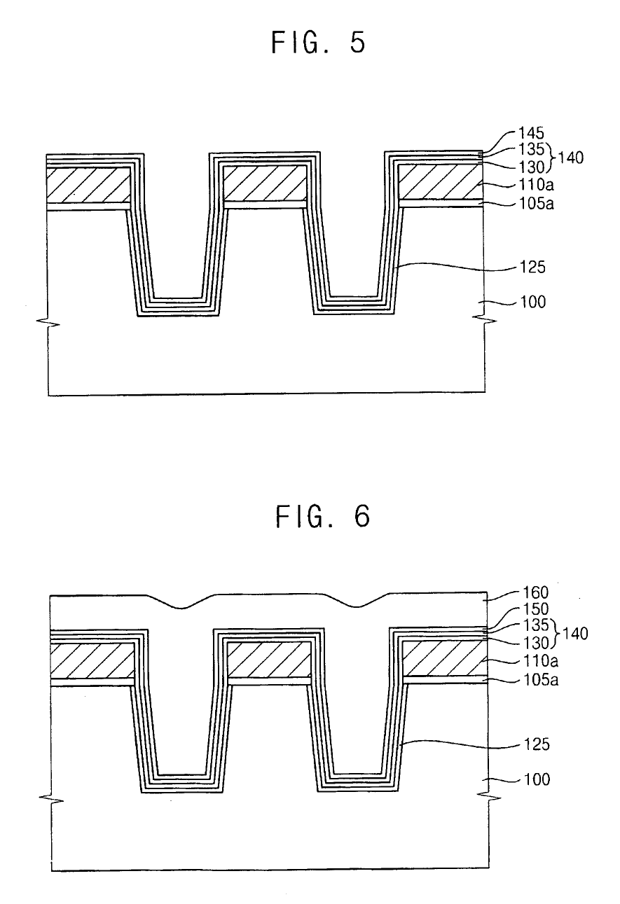

Referring to FIG. 5, a preliminary diffusion blocking layer 145 may be formed on the liner layer 140. The preliminary diffusion blocking layer 145 may include nitride. In an implementation, the preliminary diffusion blocking layer 145 may be formed by a plasma nitration process or a thermal-nitration process to prevent silicon ingredients from remaining in the preliminary diffusion blocking layer 145. In an implementation, the preliminary diffusion blocking layer 145 may have a thickness of about 10 Å to about 30 Å on an upper surface of the liner layer 140.

In an implementation, the preliminary diffusion blocking layer 145 may be formed on the liner layer 140 using the plasma nitration process, which may include processing at a temperature of about 500° C. to about 1000° C. In another implementation, the preliminary diffusion blocking layer 145 may be formed using the thermal nitration process, which may be performed in a nitrogen-containing atmosphere, i.e., an atmosphere containing a nitrogen source gas, at a temperature of, e.g., about 500° C. to about 1000° C. The nitrogen source gas may include one or more of an ammonia (NH₃) gas, a nitrous oxide (N₂O) gas, a nitric oxide (NO) gas, a nitrogen (N₂) gas, etc.

The preliminary diffusion blocking layer 145 and the liner layer 140 may effectively prevent oxygen from diffusing into the tunnel oxide layer pattern 105a, and the substrate 100 adjacent thereto, during the process for forming the isolation layer 160 that will now be described.

Referring to FIG. 6, a preliminary isolation layer (not shown) may be formed on the preliminary diffusion blocking layer 145. The preliminary isolation layer may cover the substrate 100 and may completely fill the trench 120. A thickness of the preliminary isolation layer in the trench 120 may be greater than the depth of the trench 120. The preliminary isolation layer may be formed to completely fill up the trench and to have a sufficient thickness on the preliminary diffusion blocking layer 145. In an implementation, the preliminary isolation layer may be formed of a spin-on-glass (SOG) using a spin coating process. When the preliminary isolation layer is made of the SOG in this way, the trench 120 may be completely filled up, which may reduce or eliminate the formation of voids and/or seams in the trench 120. The SOG used for the preliminary isolation layer may include, e.g., polysilazane (PSZ).

Then, a thermal treatment process may be performed to convert the preliminary isolation layer into the isolation layer 160. The preliminary diffusion blocking layer 145 may be converted into a diffusion blocking layer 150 concurrently with the conversion of the preliminary isolation layer into the isolation layer 160. That is, during the thermal treatment process, when the preliminary isolation layer is changed into the isolation layer 160, the preliminary diffusion blocking layer 145 may also be changed into the diffusion blocking layer 150 at the same time. In an implementation, the preliminary diffusion blocking layer 145 may include nitride such that the corresponding diffusion blocking layer 145 includes oxynitride, owing to oxygen diffused from the preliminary isolation layer. As mentioned above, the liner layer 140 and the diffusion blocking layer 150 may effectively prevent oxygen from being diffused in the tunnel oxide layer pattern 105a and the substrate 100 adjacent thereto when the isolation layer 160 is formed.

In an implementation, the thermal treatment process may include a first thermal treatment and a second thermal treatment. In an implementation, the first thermal treatment may be performed at a temperature of about 200° C. to about 400° C., and the second thermal treatment may be performed at a temperature of about 400° C. to about 1,000° C. For example, the second thermal treatment may be performed at a temperature of about 500° C. to about 900° C. The second thermal treatment may be performed in an atmosphere that may include at least one of a hydrogen (H₂) gas, an oxygen gas, water vapor, and a nitrogen gas, and may be performed at a pressure of about 10 Torr to about 760 Torr. In an implementation, the thermal treatment process may further include a third thermal treatment. For example, the third thermal treatment may be performed at a temperature of less than about 900° C.

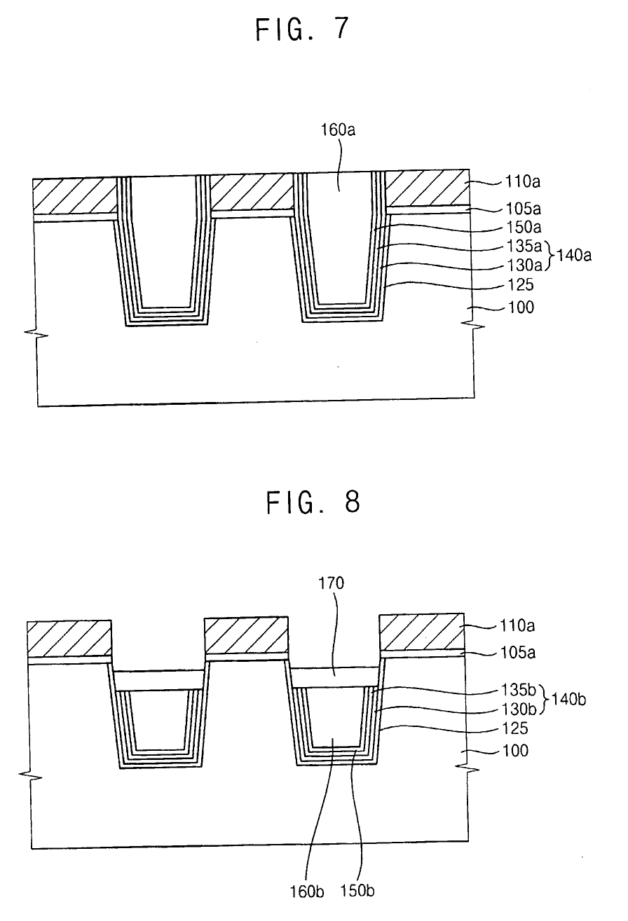

Referring to FIG. 7, the isolation layer 160, the diffusion blocking layer 150 and the liner layer 140 may be partially removed to expose the floating gate 110a. Thus, a preliminary liner layer pattern 140a, a preliminary diffusion blocking layer pattern 150a and a preliminary isolation layer pattern 160a may be successively formed in the trench 120 on which the inner oxide layer 125 is formed. The preliminary liner layer pattern 140a, the preliminary diffusion blocking layer pattern 150a and the preliminary isolation layer pattern 160a may be formed using, e.g., a chemical mechanical polishing (CMP) process and/or an etch-back process, etc. The trench 120 may be partially filled with the preliminary liner layer pattern 140a and the preliminary diffusion blocking layer pattern 150a, and the remainder of the trench 120 may be completely filled with the preliminary isolation layer pattern 160a. The preliminary isolation layer pattern 160a may extend to a height even with an upper surface of the floating gate 110a.

The preliminary liner layer pattern 140a may include a first preliminary oxide layer pattern 130a and a second preliminary oxide layer pattern 135a that are formed between the inner oxide layer 125 and the preliminary diffusion blocking layer pattern 150a.

Referring to FIG. 8, a portion of the preliminary isolation layer pattern 160a, which is positioned adjacent to the upper portion of the trench 120, i.e., an inlet portion of the trench 120, may be etched to form a recess over the trench 120. That is, an upper portion of the preliminary isolation layer pattern 160a over the trench 120 may be removed to form the recess over the trench 120. The removal of the upper portion of the preliminary isolation layer pattern 160a may yield an isolation layer pattern 160b. The preliminary isolation layer pattern 160a may partially, i.e., not completely, fill the trench 120.

During the etching process for forming the recess, upper portions of the preliminary diffusion blocking layer pattern 150a and the preliminary liner layer pattern 140a may be etched simultaneously to form a diffusion blocking layer pattern 150b and a liner layer pattern 140b, the liner layer pattern 140b including a first oxide layer pattern 130b and a second oxide layer pattern 135b. In an implementation, the isolation layer pattern 160b, the diffusion blocking layer pattern 150b and the liner layer pattern 140b may be formed by a dry etching process.

A compensation layer 170 may be formed in the recess on the isolation layer pattern 160a, the diffusion blocking layer pattern 150b and the liner layer pattern 140b. In an implementation, the compensation layer 170 may be formed using HDP oxide, e.g., using a HDPCVD process. In an implementation, an upper surface of the compensation layer 170 may be lower than a lower surface of the tunnel oxide layer pattern 105a. Accordingly, the inner oxide layer 125 on the sidewalls of the trench 120 may be partially exposed.

The compensation layer 170 may complete the isolation structure, which may include the liner layer pattern 140b, the diffusion blocking layer pattern 150b, the isolation layer pattern 160b and the compensation layer 170. In particular, the isolation structure may include the first oxide layer pattern 130b, the second oxide layer pattern 135b, the diffusion blocking layer pattern 150b, the isolation layer pattern 160b and the compensation layer 170, which may be successively formed on the inner oxide layer 125.

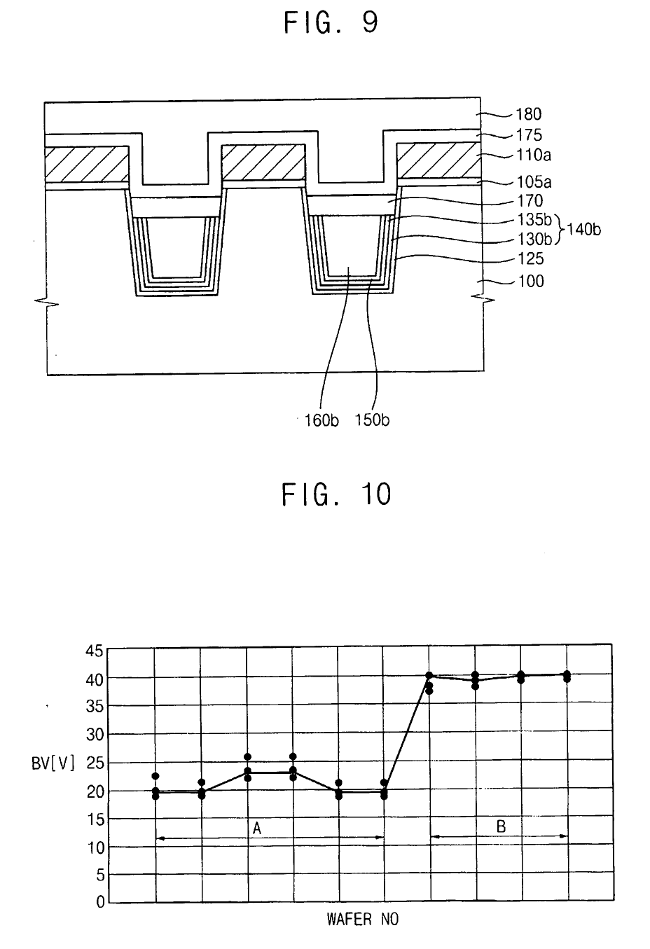

Referring to FIG. 9, a dielectric layer 175 may be conformally formed on exposed surfaces of the floating gate 110a, the tunnel oxide layer pattern 105a, the compensation layer 170, and the inner oxide layer 125. In particular, the dielectric layer 175 may be continuously formed on the upper surface of the compensation layer 170, the upper portion of the exposed inner oxide layer 125, the sidewalls of the tunnel oxide layer pattern 105a, the sidewalls of the floating gate 110a and the upper surface of the floating gate 110a. In an implementation, the dielectric layer may have an ONO structure, or may be formed using a material having a high dielectric constant.

A control gate 180 may be formed on the dielectric layer 175. In an implementation, the control gate 180 may include polysilicon doped with impurities, and may be formed by a LPCVD process. In an implementation (not shown), the control gate 180 may be formed by forming a second conductive layer on the dielectric layer 175 and then patterning the second conducive layer to form the control gate 180.

FIG. 10 illustrates a graph of breakdown voltage measurements of an isolation structure formed in accordance with an embodiment of the present invention and a comparative structure.

Referring to FIG. 10, section—A—represents breakdown voltage measurements of a conventional isolation layer on which a plasma nitride layer is formed, and section—B—indicates breakdown voltage measurements of the isolation structure including the liner layer pattern, the diffusion blocking layer pattern and the isolation layer pattern in accordance with an embodiment of the present invention.

As shown in FIG. 10, the isolation structure according to the present invention exhibits remarkably improved breakdown voltage properties compared with those in the conventional isolation layer. An isolation structure according to an embodiment of the present invention may be formed while reducing or preventing the diffusion of oxygen into the tunnel oxide layer pattern, the floating gate, and the substrate adjacent thereto during a thermal treatment process for forming the isolation layer. This may reduce or prevent deterioration of the isolation structure and may improve electric properties and a reliability of the semiconductor device having the isolation structure.

In detail, in an embodiment of the present invention, oxygen may be prevented from diffusing through the liner layer pattern and the diffusion blocking layer pattern during formation of the isolation structure. Accordingly, it may be possible to avoid generating a void in the trench, and deterioration of the tunnel oxide layer pattern, the floating gate and the substrate adjacent thereto may be prevented. Thus, the electric properties and reliability of a semiconductor device having the isolation structure may be improved.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a substrate having a trench;
a liner layer pattern on sidewalls and a bottom surface of the trench, the liner layer pattern including a first oxide layer pattern and a second oxide layer pattern;
a diffusion blocking layer pattern on the liner layer pattern; and
an isolation layer pattern in the trench on the diffusion blocking layer pattern.

2. The semiconductor device as claimed in claim 1, further comprising an inner oxide layer between the liner layer pattern and the trench.

3. The semiconductor device as claimed in claim 1, wherein the diffusion blocking layer pattern includes oxynitride.

4. The semiconductor device as claimed in claim 1, further comprising a compensation layer in the trench on the isolation layer pattern.

5. The semiconductor device as claimed in claim 4, wherein the compensation layer includes high density plasma oxide.

6. The semiconductor device as claimed in claim 1, wherein a thickness of the liner layer pattern is greater than or equal to about 100 Å.

7. The semiconductor device as claimed in claim 1, further comprising:
a tunnel oxide layer pattern on the substrate adjacent to the trench, wherein the tunnel oxide layer pattern has a floating gate thereon; and
a dielectric layer on the isolation layer pattern, the diffusion blocking layer pattern, the liner layer patter and the floating gate, wherein a control gate is on the dielectric layer.

8. The semiconductor device as claimed in claim 7, wherein the dielectric layer is on a compensation layer, the compensation layer separating the dielectric layer from the isolation layer pattern, the diffusion blocking layer pattern and the liner layer pattern.

9. A method of manufacturing a semiconductor device, comprising:
forming a trench on a surface of a substrate;
forming a liner layer pattern on sidewalls and a bottom surface of the trench, the liner layer pattern including a first oxide layer pattern and a second oxide layer pattern;
forming a diffusion blocking layer pattern on the liner layer pattern; and
forming an isolation layer pattern in the trench on the diffusion blocking layer pattern.

10. The method as claimed in claim 9, further comprising forming an inner oxide layer on the sidewalls and the bottom surface of the trench before forming the liner layer pattern.

11. The method as claimed in claim 9, wherein forming the liner layer pattern includes:
forming a first oxide layer on the sidewalls and the bottom surface of the trench; and
forming a second oxide layer on the first oxide layer.

12. The method as claimed in claim 11, wherein forming the diffusion blocking layer pattern and the isolation layer pattern includes:
forming a preliminary diffusion blocking layer on the second oxide layer;
forming a preliminary isolation layer on the preliminary diffusion blocking layer to fill up the trench; and
thermally treating the preliminary isolation layer and the preliminary diffusion blocking layer to convert the preliminary isolation layer and the preliminary diffusion blocking layer into an isolation layer and a diffusion blocking layer, respectively.

13. The method as claimed in claim 12, wherein the preliminary diffusion blocking layer is formed using a nitride and the preliminary isolation layer is formed using a polysilazane.

14. The method as claimed in claim 12, wherein thermally treating the preliminary isolation layer and the preliminary diffusion blocking layer includes a first thermal treatment at a temperature of about 200° C. to about 400° C., and a second thermal treatment at a temperature of about 400° C. to about 1,000° C.

15. The method as claimed in claim 14, wherein the second thermal treatment is performed in an atmosphere that includes one of:
a mixture of water vapor and an oxygen gas, and
a mixture of water vapor and a nitrogen gas.

16. The method as claimed in claim 12, wherein the preliminary isolation layer and the preliminary diffusion blocking layer are converted into the isolation layer and the diffusion blocking layer simultaneously.

17. The method as claimed in claim 12, further comprising forming the isolation layer pattern, the liner layer pattern, and the diffusion blocking layer pattern by partially removing respective portions of the isolation layer, a liner layer, and the diffusion blocking layer, such that an uppermost extent of the isolation layer pattern, an uppermost extent of the liner layer pattern, and an uppermost extent of the diffusion blocking layer pattern are below an upper surface of the substrate.

18. The method as claimed in claim 9, further comprising:
forming a tunnel oxide layer pattern and a floating gate on the substrate, the tunnel oxide layer pattern and the floating gate being adjacent to the trench;
forming a dielectric layer on the isolation layer pattern, the diffusion blocking layer pattern, the liner layer pattern, and the floating gate; and
forming a control gate on the dielectric layer.

19. The method as claimed in claim 18, wherein forming the tunnel oxide layer pattern and the floating gate includes forming a tunnel oxide layer and a floating gate layer on the substrate before forming the trench.

20. The method as claimed in claim 9, wherein a thickness of the liner layer pattern is greater than or equal to about 100 Å.
